(19) United States
(12) Patent Application Publication
(10) Pub. No.: US 2002/0076843 A1
(43) Pub. Date: Jun. 20, 2002

(54) Semiconductor structure having a silicon oxynitride ARC layer and a method of forming the same

(76) Inventors: Hartmut Ruelke, Dresden (DE); Martin Mazur, Pulsnitz (DE); Minh Van Ngo, Fremont, CA (US)

Correspondence Address: Williams, Morgan & Amerson, P.C., Suite 250, 7676 Hillmont, Houston, TX, 77040, US

(21) Appl. No.: 09/851,899

(22) Filed: May 9, 2001

(30) Foreign Application Priority Data
Dec. 15, 2000 (DE) 100 62 660.2

(51) Int. Cl. H01L 21/00

(52) U.S. Cl. 438/29

(57) ABSTRACT

A semiconductor structure is disclosed having a silicon oxynitride ARC layer formed over a material layer to be patterned, wherein the ARC layer comprises a protection layer that prevents contact of the photoresist with nitrogen atoms. The ARC layer is formed by plasma-enhanced chemical vapor deposition so that the optical properties of the ARC layer, such as thickness, refractive index and extinction coefficient, can be precisely controlled.

### BACKGROUND OF THE INVENTION

1. Field of the Invention

The present invention relates to manufacturing of integrated circuits, and particularly to a semiconductor structure including an anti-reflective coating (ARC) and a method of forming an ARC layer that is preferably used during patterning of layers with underlying layers of high reflectivity, such as a metallization layer in semiconductor devices.

2. Description of the Related Art

The manufacturing process of integrated circuits involves the fabrication of numerous semiconductor elements such as insulated gate field effect transistors within a small chip area. In order to steadily increase integration density and improve device performance, feature sizes of the semiconductor elements are steadily decreasing. At the same time, economic constraints require a high yield and throughput in manufacturing the semiconductor devices, while, on the other hand, high quality and reliability of the end products are of great importance.

The fabrication of modem integrated circuits requires a huge number of procedural steps for completing the final device. A plurality of these steps involve photolithography which is used to transfer mask patterns into a photoresist layer so as to pattern the material layer underlying the photoresist. Due to the steadily decreasing feature sizes of the semiconductor devices, it is essential not only to steadily reduce the wavelength of the light sources, but also to optimize the process of energy deposition in the photoresist layer, since already minor deviations from the desired pattern may result in irregularities of the final pattern that will reduce reliability of the final device or even cause a total failure. One source of such undesired and uncontrollable energy deposition in the photoresist resides in the reflectivity of the underlying material layer(s) to be patterned. In particular, if one of the underlying material layers comprises a metal, such as aluminum, for patterning a metallization layer in the semiconductor device, the reflectivity of this metal layer may exceed a value of 90%. Since the light reflected from the underlying layer(s) will expose resist portions that are intended to remain unexposed, resulting in an undesired broadening of features, it is necessary for achieving accurate feature sizes to suppress reflection of an underlying layer as much as possible. To this end, usually anti-reflective coatings (ARCs) are used in the photolithography process for patterning features of critical dimensions.

An ARC layer formed on top of a layer to be patterned is typically designed so as to reduce the amount of light that is reflected back into the photoresist from the underlying layer. For this purpose, three optical parameters, namely refractive index “n,” extinction coefficient “K” and thickness “d” of the ARC layer, have to be properly selected such that an appropriate phase shift is created between the light reflected on the interface between the ARC layer and the underlying material layer, for example, aluminum, and the light reflected at the interface between the ARC layer and the photoresist. If the above-mentioned three parameters “n,” “k,” “d” are properly adjusted to the wavelength of the light source used, the reflectivity of underlying layers can be drastically reduced. To achieve optimum results, however, a very strict control of process parameters for forming the ARC layer, for example, with regard to the thickness of the ARC layer, is required. Precise control of the three optical parameters “n,” “k,” “d” of the ARC layer for adjusting the optical properties of the ARC layer, however, does not represent the only requirement imposed on the ARC layers in modern ultra-high density integrated circuits. The characteristics of the ARC layers must also be compatible with other materials, such as the photoresist, and process flows, such as etching, involved in manufacturing the semiconductor device.

One candidate for use as an ARC layer in conventional photolithographic technology is titanium nitride (TiN). Titanium nitride reduces the reflectivity of an underlying interconnect metal, such as aluminum, from about 90% to about 25%. For device features of less than 0.4 microns, a reflectivity reduction obtained by a titanium nitride layer is inappropriate for attaining reproducible images.

Accordingly, efforts have been made to find suitable candidates for an ARC layer meeting the requirements in modern lithography. Bencher, et al., in “Dielectric Anti-Reflective Coatings for DUV Lithography,” Solid State Technology, March 1997, pp. 109-14, therefore, propose a silicon oxynitride layer as a dielectric ARC layer for obtaining a near zero reflectivity from an underlying aluminum layer. In this document, a process flow for plasma-enhanced chemical vapor deposition (PECVD) is simulated to verify the feasibility of forming a silicon oxynitride ARC layer meeting the tight restrictions required to form an efficient ARC layer for patterning an aluminum metallization layer with 0.3 μm features using a wavelength of 248 nm. Measurements performed on test wafers showed that the silicon oxynitride ARC layer resulted in a swing curve, i.e., a curve representing the variation of the critical dimension of a feature with respect to the thickness of the photoresist applied, of less than 3% for a 0.35 μm feature line. In comparison, a conventional TiN ARC layer exhibited a swing curve having a variation of about 9%. Although a significant improvement has been achieved, this document does not address the problems involved with smaller feature sizes and different materials, other than aluminum, used in cutting-edge integrated circuits, and also does not explicitly address the problem of the interaction of the ARC layer with UV photoresists, in particular the reaction of nitrogen with the photoresist material.

Accordingly, a need exists for an improved ARC layer that is usable for feature sizes beyond 0.3 μm, and that substantially avoids interaction with adjacent material layers, particularly with the photoresist, and for a method of forming the ARC layer.

### SUMMARY OF THE INVENTION

According to one aspect of the present invention a semiconductor structure comprises a substrate having at least one material layer formed thereon, and an anti-reflective coating layer comprising silicon oxynitride formed on the material layer. The semiconductor structure further includes a protection layer formed on the anti-reflective coating layer, wherein the protection layer substantially comprises silicon and oxygen.

According to this aspect of the present invention, the semiconductor structure comprises the protection layer formed on the silicon oxynitride ARC layer that allows the deposition thereon of a photoresist layer, thereby substantially avoiding a reaction between the nitrogen of the ARC layer and the photoresist formed over the protection layer. In this way, small critical dimensions may be reliably obtained since the reflectivity of an underlying layer, such as a dielectric inter-layer used in a copper damascene process for forming local interconnects, is efficiently reduced while a reaction between the photoresist and the nitrogen in the ARC layer is effectively suppressed, thereby eliminating pattern deformation in the underlying layer. Accordingly, precisely formed patterns in the underlying layer are obtained.

In further embodiments of the present invention, the thickness of the silicon oxynitride layer is in the range of 20-80 nm, and, in one particular embodiment, in the range of 57-63 nm. The thickness of the protection layer may be in the range of about 1 nm to about 5 nm, and, in one particular embodiment, in the range of about 2 nm to about 3 nm. This arrangement allows for an appropriate adaptation of the optical parameters of the ARC layers to an exposure wavelength of approximately 248 nm and less for patterning a dielectric inter-layer on conductive layers, such as aluminum and copper, used in a dual or single damascene stack in a sophisticated manufacturing process of modem integrated circuits.

According to another aspect of the present invention, a method of forming an ARC layer over a semiconductor structure comprises depositing a silicon oxynitride layer on the semiconductor structure by plasma enhanced chemical vapor deposition using silane and nitrogen oxide, and forming a protection layer, substantially comprising silicon and oxygen, on the silicon oxynitride layer.

The deposition of the silicon oxynitride layer by plasma enhanced chemical wafer deposition allows a precise control of the thickness of the silicon oxynitride layer and of the stoichiometric composition of the layer. The overlying protection layer allows the deposition and the further processing of a photoresist layer with an extremely reduced chemical reaction between the nitrogen contained in the ARC layer and the photoresist due to a significantly reduced presence of nitrogen atoms in the protection layer.

In a further embodiment, the protection layer is formed by exposing the silicon oxynitride layer to nitrogen oxide in a plasma ambient. Accordingly, the thickness and the amount of silicon-oxygen-bondings in the protection layer can be precisely controlled by adjusting corresponding process parameters. Since using nitrogen oxide in plasma reactors is a standard manufacturing process, the method of the present invention may easily be incorporated in a conventional process flow. Moreover, the silicon oxynitride layer and the protection layer may be formed in a so-called in situ process, i.e., in a process using the same reaction chamber without the necessity of an intermediate wafer handling step, or without the necessity of breaking the vacuum in the chamber.

### BRIEF DESCRIPTION OF THE DRAWINGS

The invention may be understood by reference to the following description taken in conjunction with the accompanying drawings, in which like reference numerals identify like elements, and in which:

FIG. 1 schematically shows the basic concept of an anti-reflective coating; and

FIG. 2 is a graph showing experimental results obtained by measurements with a semiconductor structure in conformity with one embodiment of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

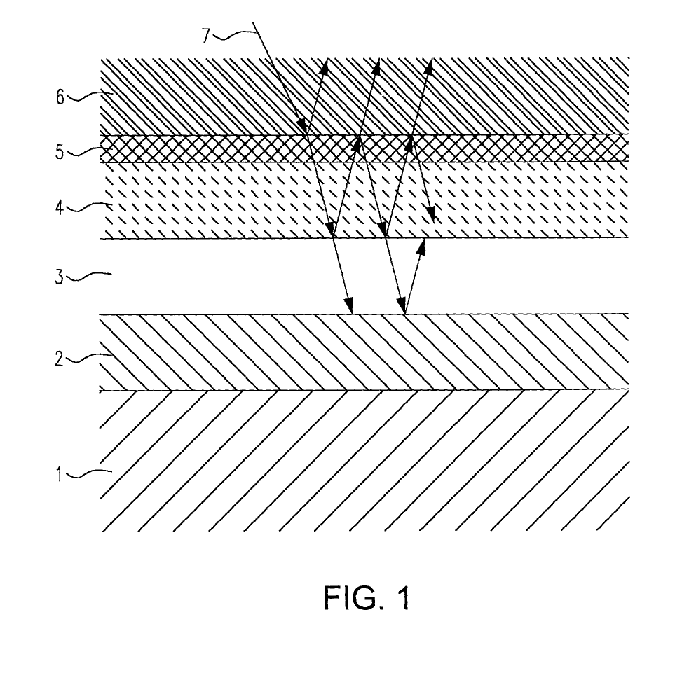

FIG. 1 shows the basic concept of an anti-reflective coating (ARC) in accordance with one embodiment of the present invention. In FIG. 1, a substrate 1, which may comprise a plurality of different material layers so as to constitute a large number of individual semiconductor elements such as field effect transistor devices, is provided with a conductive layer 2 that may include conductive portions formed therein. The conductive portions may include materials such as aluminum, copper, titanium, tantalum, and the like. In the present case, the conductive layer 2 is a layer including conductive portions substantially formed of copper. A dielectric inter-layer 3 is formed on the conductive layer 2 and is to be patterned in conformity, for example, with a single or dual damascene copper back end process. Located above the dielectric inter-layer 3 is an ARC layer 4 having a protection layer 5 formed on its upper surface. Finally, a photoresist layer 6, to be exposed and developed, is formed on the protection layer 5 and over the ARC layer 4.

During exposure of the photoresist layer 6, light 7 is directed to the photoresist layer 6 by a light source (not shown), such as a so-called wafer stepper or scanner (not shown). In the present case, the exposure wavelength is approximately 248 nm, although the exposure wavelength may vary. Ideally, light incident on the photoresist layer 6 should be absorbed within the photoresist layer 6 without any reflections from underlying layers. Since each different layer normally has a different index of refraction, light that impinges on the interface between two different layers is partially reflected and partially transmitted, such that light reflected on underlying interfaces reaches the photoresist layer 6 from the substrate side. This additional light reflected from underlying layers, however, results in an undesired broadening of corresponding feature sizes to be patterned in the dielectric inter-layer 3.

For this reason, the ARC layer 4 is provided and is optimized in its refractive index “in,” its extinction coefficient “k,” and its layer thickness “d” to cause a destructive interference of the light reflected on the interface between the photoresist layer 6 and the protection layer 5 and the light that is reflected between the ARC layer 4 and the underlying dielectric inter-layer 3. Since the dielectric inter-layer 3 is usually transparent, the underlying conductive layer 2 may also contribute an amount of back-coupled light reflected at the interface between the dielectric inter-layer 3 and the conductive layer 2 that would finally reach the photoresist layer 6. Hence, the optical parameters “n,” “k” and “d” of the ARC layer 4 are selected in conformity with the corresponding optical parameters of the underlying dielectric inter-layer 3 so as to also minimize the amount of light reflected from the conductive layer 2. Suitable parameter values for “n,” “k,” “d” may be obtained from calculations simulating multiple reflections in a plurality of subsequent material layers. Patterning of a dielectric inter-layer and/or of a metallization layer having feature sizes with a critical dimension of 0.3 μm and less is particularly difficult, since the reflectivity of the conductive layer 2 may be very high, and even reaches about 90% in the case of an aluminum layer.

A further issue in modem lithography resides in the fact that UV photoresists tend to react adversely with nitrogen during exposure and development of the photoresist material. To eliminate the reaction between the photoresist and the nitrogen contained in the ARC layer 4 during exposure and development of the photoresist layer 6, a thin protection layer 5 is formed between these two layers. The protection layer 5 substantially comprises silicon-oxygen-bondings, so that any possible contact between nitrogen and the photoresist material is reduced to a minimum. For example, the protection layer 5 may be comprised of silicon-rich oxide, silicon oxide, TEOS based silicon-oxide, etc. The concentration of nitrogen of the protection layer 5 is less than 0.01 weight percent, and the nitrogen concentration of the protection layer 5 at a surface that is not in contact with the ARC layer 4 is substantially equal to zero. The thickness of the protection layer 5 is set to a range from approximately 1-5 nm so that the optical characteristics of the combined layers 4 and 5 are substantially determined by the optical characteristics of the ARC layer 4. Moreover, the protection layer 5 may be formed such that the refractive index of the protection layer 5 is substantially equal to that of the ARC layer 4 to avoid reflection at the interface between these two layers. In the present embodiment, the refractive index “n” of the ARC layer 4 and the protection layer is adjusted to approximately 2.2 to 2.6, the extinction coefficient “k” is set to 0.8 to 0.9, and the thickness “d” of the ARC layer 4 for the single and dual damascene process is set to about 60 nanometers±5%.

A typical process flow for forming the ARC layer 4 comprised of silicon oxynitride and the protection layer 5 in accordance with the present invention will now be described. After providing the substrate 1, comprising the one or more additional material layers formed thereon, forming the conductive layer 2 and depositing thereon the dielectric inter-layer 3, the substrate 1 is inserted into the reaction chamber (not shown) of a single or dual PECVD apparatus. Since the optical parameters, particularly the thickness of the ARC layer 4, have to be precisely controlled, a plasma enhanced CVD process is used for the formation of the ARC layer 4. Other methods such as PVD, spin-on processes, etc. could also be used to form the ARC layer 4. In addition to a precise control of the thickness of the ARC layer 4, the optical parameters refractive index “n” and extinction coefficient “k” of the ARC layer 4 can be adjusted during the CVD deposition process by varying the ratio of the gaseous components fed into the reaction chamber.

At the beginning of the deposition process, a pressure of approximately 4.0-8.0 Torr is applied to the reaction chamber and nitrogen, used as a carrier gas, with a flow rate of approximately 8000±1000 sccm is introduced into the chamber. Thereafter, reaction gases, such as silane and nitrogen oxide, are fed into the reaction chamber with a ratio of approximately 2:1 to 3:1, wherein the selected ratio determines the finally obtained refractive index and extinction coefficient of the ARC layer 4. Typically, silane (SiH₄) is fed with a flow rate of approximately 400-600 sccm and nitrogen oxide (N₂O) is fed with a flow rate of approximately 120-250 sccm into the reaction chamber. With a high frequency power of about 350-550 Watts and a temperature in the range 380-420° C., a typical deposition rate of 10 nm/second is obtained. This process will result in the formation of a silicon oxynitride ARC layer 4 having a thickness ranging from approximately 57 to about 63 nm.

As previously noted, modem photoresists such as UV 110, used for deep ultraviolet (DUV) exposure, are sensitive to nitrogen during exposure, post exposure bake and development, and give rise to a deformation in the final features that are referred to as “footing” and “scumnming.” These effects result from the reaction products formed at portions of the interface between the photoresist and the underlying nitrogen-containing ARC layer, e.g. titanium nitride, silicon nitride, non-stochiometric silicon nitride, silicon oxy-nitride. These “additional” features are transferred into the underlying layer to be patterned in the subsequent etching process to result in a corresponding deviation from the desired shape at the foot of the pattern. Hence, the protection layer 5 is formed on the upper surface of the ARC layer 4 so as to drastically reduce the number of nitrogen atoms to which the photoresist layer 6 will be exposed. To this end, a plasma treatment subsequent to the deposition process used to form the ARC layer 4 is performed, preferably as an in situ process, with a pressure of about 3.0-5.0 Torr and a temperature of 380-420° C., wherein the high frequency power is reduced to about 50-200 Watts. Nitrous oxide (N₂O) gas is flowed with a flow rate of approximately 300-500 sccm into the reaction chamber, typically for approximately ten seconds. During this treatment, a 2-3 nm thick protection layer 5 with a considerably reduced nitrogen concentration of less than about 0.01 weight percent is formed on top of the silicon oxynitride ARC layer 4. Preferably, the nitrogen concentration of the protection layer 5 is adjusted to be substantially equal to zero. The protection layer 5 substantially comprises silicon-oxygen-bondings so that a contact of the photoresist layer 6 with nitrogen is drastically reduced, and hence footing and scumming in the final feature is avoided. The silicon concentration of the protection layer 5 is substantially the same as that of the ARC layer 4, and hence, no abrupt change of the refractive index will occur since the optical characteristics, for example, the refractive index of the layers 4 and 5, are primarily determined by the silicon content.

Compared to a typical prior art TiN ARC layer, the optical properties of the silicon oxynitride ARC layer 4 in accordance with the present invention can be tuned in a considerably wider range to match the DUV exposure requirements. The amount of silicon in the silicon oxynitride ARC layer 4 that is mainly responsible for optical properties of the ARC layer 4 can easily be tuned by variation of the silane to nitrogen oxide ratio during the CVD deposition process. Furthermore, the thickness of the silicon oxynitride ARC layer 4 may easily and precisely be adapted to the underlying layer stack and to the photoresist material used. It should be noted that the ARC layer 4 may be left on the single damascene stack or on top of it and/or within the dual damascene layer stack. It is also possible, however, to reduce the ARC layer 4 during the plasma etch process for patterning the dielectric inter-layer 3. Furthermore, the ARC layer 4 may be removed during a chemical mechanical polishing process of the metal film that is deposited on the dielectric interlayer 3 after patterning the same.

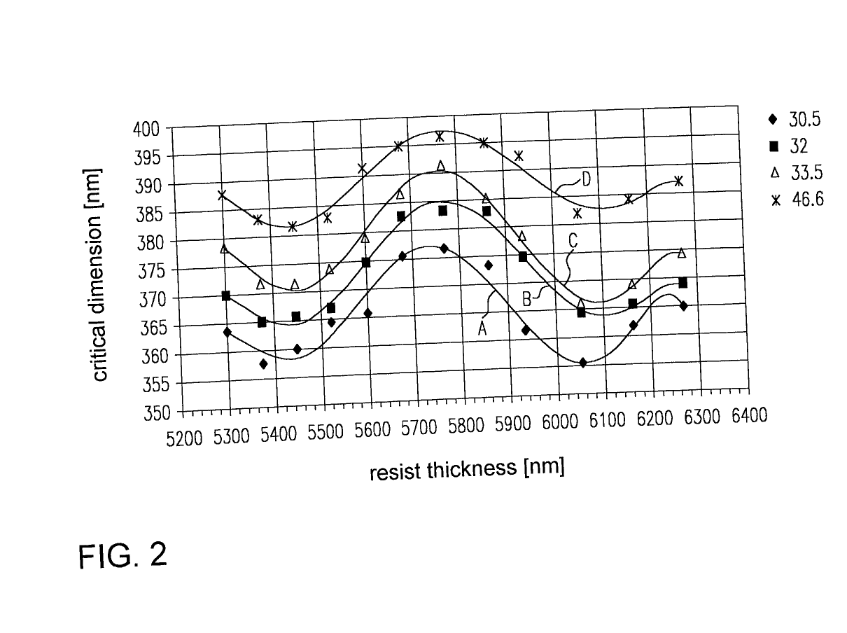

FIG. 2 is a graph showing experimental results of a semiconductor structure having a silicon oxynitride ARC layer 4 formed in accordance with the present invention. In FIG. 2, the variation of feature sizes is shown with respect to a variation of the thickness of the photoresist layer 6 for an arrangement as shown in FIG. 1, ie., for a dielectric inter-layer stack as used during a single damascene copper back end process. In FIG. 2, Curve A represents the variation of feature sizes, e.g., the width of a single line, for different thicknesses of the photoresist layer 6 used in the photolithography step for an exposure dose of 30.5 mJ/cm². Curve B shows the corresponding dependence for an exposure dose of 32 mJ/cm², Curve B shows the corresponding relationship for an exposure dose of 33.5 mJ/cm², and Curve D shows the corresponding relationship for an exposure dose of 36.5 mJ/cm². As can be seen from these swing curves, the minima and maxima of these curves are located substantially at the same values of the photoresist thicknesses for the different exposure doses, and, for example, a value of about 545 nm for the photoresist thickness results in a minimum variation of the feature sizes.

A further analysis of test wafers comprising an ARC layer 4 in conformity with the present invention showed the following results. In a via mask formed in a dielectric interlayer, a pattern of dense lines exhibited critical dimensions having a width of approximately 417.5 nm with a standard deviation of 2.6 nm. A pattern of isolated lines, ie., lines that are spaced apart by a distance that is large compared to the line width, showed a critical dimension of 414.1 nm with a standard deviation of 2.8 nm. The critical dimensions of a raster pattern was 417.5 nm with a standard deviation of 3.4 nm. Hence, an average critical dimension of 416.4 nm with a standard deviation of 3.3 nm is obtained. Furthermore, it is evident that a small difference between isolated lines and dense structures is obtained which is required in processing of product wafers.

In addition, test structures were formed using a metallization mask and yielded the following results. In a dense structure, a critical dimension of 281.1 nm with a standard deviation of 1.3 nm was obtained. In a structure with dense spaces, the critical dimension was 281.5 nm with a standard deviation of 1.6 nm. For an isolated feature, a critical dimension of 283.4 nm with a standard deviation of 1.7 nm was obtained. As in the previous case, a good control of the critical dimension for all features was achieved, wherein a different layer stack compared to the previous experiment was formed underneath the ARC layer 4.

As the experimental results show, the semiconductor structure comprising the silicon oxynitride ARC layer 4 and the method for forming the same are well-suited for patterning a dielectric inter-layer 3 formed over a conductive layer 4, or for patterning of metallization layers with critical feature sizes of 300 nm and less. Furthermore, due to the provision of a protection layer 5 on top of the ARC layer 4 that does not adversely affect the optical properties of the ARC layer 4, but instead avoids reaction of the nitrogen present in the ARC layer 4 with the photoresist material 6, features can be patterned without exhibiting deformations known as footing or scumming defects. Since the ARC layer 4 in accordance with the present invention is formed by plasma-enhanced CVD deposition, the optical parameters such as thickness of the ARC layer 4, refractive index, and extinction coefficient may be precisely adjusted within a wide range so that the ARC layer 4 can be adapted to a variety of process flows including the patterning of inter-dielectric layers and metallization layers. Moreover, the protection layer 5 may be formed in an in situ process so that the ARC layer 4 including the protection layer 5 may be formed in a single process step employing standard semiconductor manufacturing process technology, thereby allowing the method to be easily integrated in a standard process flow.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A semiconductor structure, comprising:
a substrate having at least one material layer formed thereon;
an anti-reflective coating layer comprising silicon oxynitride formed on the at least one material layer; and
a protection layer formed on the anti-reflective coating layer, the protection layer substantially comprising silicon and oxygen.

2. The semiconductor structure of claim 1, wherein a nitrogen concentration of the protection layer at a surface thereof that is not in contact with the anti-reflective coating is substantially equal to zero.

3. The semiconductor structure of claim 1, wherein said anti-reflecting coating layer has a thickness in the range of about 20 nm to about 80 nm.

4. The semiconductor structure of claim 1, wherein said anti-reflecting coating layer has a thickness in the range of about 57 nm to about 63 nm.

5. The semiconductor structure of claim 1, wherein said protection layer has a thickness in the range of about 1 nm to about 5 nm.

6. The semiconductor structure of claim 1, wherein said protection layer has a thickness in the range of about 2 nm to about 3 nm.

7. The semiconductor structure of claim 1, wherein said protection layer has a refractive index that is substantially equal to a refractive index of said anti-reflective coating layer.

8. The semiconductor structure of claim 1, further comprising a conductive layer comprising a metal.

9. The semiconductor structure of claim 8, wherein said at least one material layer is a dielectric inter-layer formed over the conductive layer.

10. The semiconductor structure of claim 1, wherein said anti-reflective coating layer has a refractive index in a range of about 2.20 to about 2.60.

11. The semiconductor structure of claim 1, wherein said anti-reflective coating layer has an extinction coefficient in a range of about 0.80 to about 0.90.

12. The semiconductor structure of claim 1, further comprising a photoresist layer formed in contact with the protection layer.

13. The semiconductor structure of claim 8, wherein the metal comprises at least one of copper and aluminum.

14. A method of forming an ARC layer over a semiconductor structure, comprising:
depositing a silicon oxynitride layer on the semiconductor structure by plasma enhanced chemical vapor deposition using silane and nitrogen oxide, and
forming a protection layer, substantially comprising silicon and oxygen, on the silicon oxynitride layer.

15. The method of claim 14, wherein a concentration of nitrogen of the protection layer at a surface thereof that is not in contact with the silicon oxynitride layer is substantially equal to zero.

16. The method of claim 14, wherein a refractive index of the ARC layer is adjusted by adjusting a ratio of silane and nitrogen oxide during the deposition step.

17. The method of claim 16, wherein the ratio is varied from about 2:1 to about 3:1.

18. The method of claim 14, wherein a thickness of the ARC layer is set to a value in the range from about 20 nm to about 80 nm.

19. The method of claim 14, wherein a thickness of the ARC layer is set to a value in the range from about 57 nm to about 63 nm.

20. The method of claim 14, wherein the protection layer is formed by exposing the silicon oxynitride layer to a plasma ambient including nitrogen and oxygen.

21. The method of claim 20, wherein a silicon concentration of the protection layer is substantially equal to that of the silicon oxynitride layer such that a refractive index of the protection layer is substantially identical to that of the silicon oxynitride layer.

22. The method of claim 14, wherein depositing the silicon oxynitride layer and forming the protection layer is an in situ process.

23. The method of claim 14, wherein a thickness of the protection layer is adjusted to be in a range of about 1 nm to about 5 nm.

24. The method of claim 23, wherein a combined thickness of the silicon oxynitride layer and the protection layer is in the range from about 57 nm to about 63 nm.

25. The method of claim 23, further comprising forming a conductive layer comprising copper on the semiconductor structure, and forming a dielectric inter-layer over the conductive layer, prior to depositing the silicon oxynitride layer.

26. The method of claim 14, further comprising depositing a photoresist layer over the silicon oxynitride layer, wherein the protection layer substantially eliminates a reaction of photoresist material with nitrogen contained in the silicon oxynitride layer.
